(19) United States
(12) Patent Application Publication
(10) Pub. No.: US 2026/0369516 A1
(43) Pub. Date: Nov. 19, 2026

(54) Charged Particle Beam Apparatus and Alignment Marker Detection Method

(71) Applicant: Hitachi High-Tech Corporation, Minato-ku, Tokyo (JP)

(72) Inventors: Okuto IKEDA, Tokyo (JP); Daiji KIRIHATA, Tokyo (JP); Takashi SHIDARA, Tokyo (JP); Hiromi MISE, Tokyo (JP)

(21) Appl. No.: 19/155,300

(22) PCT Filed: Feb. 27, 2023
(86) PCT No.: PCT/JP2023/007130

§ 371 Date: Aug. 11, 2025

(51) Int. Cl. H01J 37/22; H01J 37/244; H01J 37/28

(52) U.S. Cl. CPC H01J 37/22; H01J 37/244; H01J 37/28; H01J 2237/221; H01J 2237/2448; H01J 2237/2806

(57) ABSTRACT

To detect an alignment marker without changing an observation magnification, a charged particle beam apparatus includes: a sample holding portion configured to hold a sample; a charged particle beam source configured to irradiate the sample with a charged particle beam; a detector configured to detect a secondary particle emitted from the sample and output a detection signal; and a control unit configured to generate an observation image of the sample based on the detection signal and control each unit, in which the sample is provided with an alignment marker serving as a reference point for specifying a position on the sample and a guide marker having a shape indicating a direction in which the alignment marker is present, and the control unit detects the guide marker based on the observation image and moves a field of view in a direction indicated by the guide marker.

### TECHNICAL FIELD

The present invention relates to a charged particle beam apparatus that generates an observation image of a sample by irradiating the sample with a charged particle beam, and particularly to an alignment marker detection method used for alignment of the sample.

### BACKGROUND ART

A charged particle beam apparatus is an apparatus that detects secondary particles such as secondary electrons emitted from a sample by irradiation with a charged particle beam such as an electron beam to generate an observation image of the sample, and is used, for example, when a foreign substance or a defect on a sample surface detected under an optical microscope is observed in detail. An alignment marker is created on the sample or a sample holder as a reference point for specifying a position of the foreign substance detected under the optical microscope under the charged particle beam apparatus.

Since optical axes of the optical microscope and the charged particle beam apparatus do not completely coincide with each other, the alignment marker located at a center of the field of view under the optical microscope may deviate from a center of the field of view under the charged particle beam apparatus. In particular, it takes time to detect an alignment marker deviated from the field of view of the charged particle beam apparatus.

PTL 1 discloses that a plurality of sub-markers each having a planar shape different from that of an alignment marker are disposed around the alignment marker in all directions of up, down, left, right, and oblique in a plan view. That is, by detecting the sub-markers disposed around the alignment marker, even an alignment marker deviated from the field of view can be detected in a relatively short time.

### CITATION LIST

### Patent Literature

PTL 1: JP2006-135104A

### SUMMARY OF INVENTION

### Technical Problem

However, in PTL 1, since a direction in which the field of view is moved cannot be appropriately set after the sub-markers are detected, the alignment marker is detected by reducing an observation magnification and enlarging the field of view. When the observation magnification is changed, it takes time to adjust the focus.

Therefore, an object of the invention is to provide a charged particle beam apparatus and an alignment marker detection method capable of detecting an alignment marker without changing an observation magnification.

### Solution to Problem

To achieve the above object, the present invention provides a charged particle beam apparatus including: a sample holding portion configured to hold a sample; a charged particle beam source configured to irradiate the sample with a charged particle beam; a detector configured to detect a secondary particle emitted from the sample and output a detection signal; and a control unit configured to generate an observation image of the sample based on the detection signal and control each unit, in which the sample is provided with an alignment marker serving as a reference point for specifying a position on the sample and a guide marker having a shape indicating a direction in which the alignment marker is present, and the control unit detects the guide marker based on the observation image and moves a field of view in a direction indicated by the guide marker.

The invention is an alignment marker detection method for detecting an alignment marker serving as a reference point for specifying a position on a sample held by a sample holding portion, based on an observation image generated by irradiating the sample with a charged particle beam, the alignment marker detection method including: a detection step of detecting, based on the observation image, a guide marker having a shape indicating a direction in which the alignment marker is present; and a movement step of moving a field of view in the direction indicated by the guide marker.

### Advantageous Effects of Invention

According to the invention, a charged particle beam apparatus and an alignment marker detection method capable of detecting an alignment marker without changing an observation magnification can be provided.

### BRIEF DESCRIPTION OF DRAWINGS

FIG. 1 is a diagram illustrating an example of an overall configuration of a charged particle beam apparatus according to Embodiment 1.

FIG. 2 is a diagram illustrating an alignment marker.

FIG. 3 is a diagram illustrating guide markers.

FIG. 4 is a diagram illustrating an arrangement of the guide markers.

FIG. 5 is a diagram illustrating an initial guide marker.

FIG. 6 is a diagram illustrating an example of a processing flow of creating each marker.

FIG. 7 is a diagram illustrating an example of a processing flow of detecting the alignment marker.

FIG. 8 is a diagram illustrating a template image.

FIG. 9 is a diagram illustrating movement of a field of view.

FIG. 10 is a diagram illustrating guide markers each indicating a distance.

FIG. 11 is a diagram illustrating a link marker.

FIG. 12 is a diagram illustrating an example of a processing flow of creating the link marker.

FIG. 13 is a diagram illustrating an example of a processing flow of sequentially detecting a plurality of alignment markers.

### DESCRIPTION OF EMBODIMENTS

Hereinafter, embodiments of a charged particle beam apparatus according to the invention will be described with reference to the accompanying drawings. A charged particle beam apparatus is an apparatus that irradiates a sample with a charged particle beam such as an electron beam, detects secondary particles such as secondary electrons, reflected electrons, Auger electrons, or X-ray photons emitted from the sample, and generates an observation image of the sample. Hereinafter, a scanning electron microscope (SEM) that detects the secondary electrons emitted from the sample will be described as an example of the charged particle beam apparatus.

### Embodiment 1

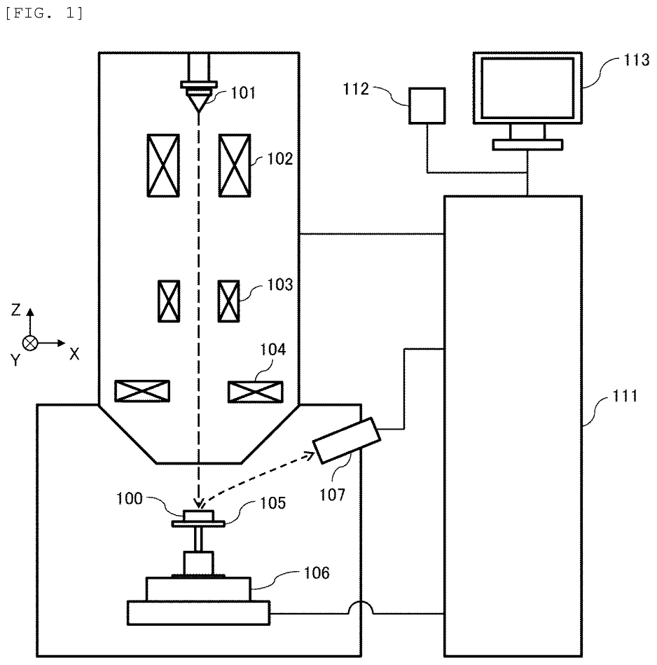

An overall configuration of a scanning electron microscope according to Embodiment 1 will be described with reference to FIG. 1. The scanning electron microscope includes an electron source 101, a condenser lens 102, a deflector 103, an objective lens 104, a sample stage 106, a detector 107, a control unit 111, an input unit 112, and a display unit 113. Hereinafter, each unit will be described.

The electron source 101 is a device that generates an electron beam to be emitted to the sample 100 by emitting and accelerating electrons. The electron beam generated by the electron source 101 travels along an optical axis, is focused by the condenser lens 102, is deflected by the deflector 103, and is focused by the objective lens 104. By deflection in the deflector 103, a surface of a sample 100 is two-dimensionally scanned with the electron beam.

The sample stage 106 is a device placed with a sample holder 105 that grips the sample 100 and moving the sample holder 105 in a horizontal direction and a vertical direction. The sample holder 105 and the sample stage 106 function as a sample holding portion that holds the sample 100.

The detector 107 is a device that detects secondary electrons emitted from the surface of the sample 100 scanned with the electron beam, and transmits a detection signal to the control unit 111.

The control unit 111 is a device that controls the electron source 101, the condenser lens 102, the deflector 103, the objective lens 104, and the sample stage 106, and is, for example, a general-purpose computer. The control unit 111 includes a processor such as a central processing unit (CPU) and a memory such as a random access memory (RAM) or a read only memory (ROM). The control unit 111 executes processing of generating an observation image of the sample 100 based on the detection signal transmitted from the detector 107 and calculating a new image using a plurality of the observation images. The processing by the control unit 111 may be implemented by the processor executing a program loaded on the memory. A part of the control unit 111 may be implemented by hardware such as a dedicated circuit board.

The control unit 111 is connected to the input unit 112 and the display unit 113. The input unit 112 is a device for an operator to input imaging conditions of the observation image, and is, for example, a keyboard, a mouse, or a touch panel. The display unit 113 is a device that displays the imaging conditions and the observation images, and is, for example, a liquid crystal display or a touch panel.

The charged particle beam apparatus such as a scanning electron microscope is suitable for detailed observation of the sample 100, and is used, for example, for detailed observation of foreign substances or defects on the sample surface detected under an optical microscope. An alignment marker is created on the sample 100, the sample holder 105, or the sample stage 106 as a reference point for specifying positions of the foreign substances detected under the optical microscope under the charged particle beam apparatus.

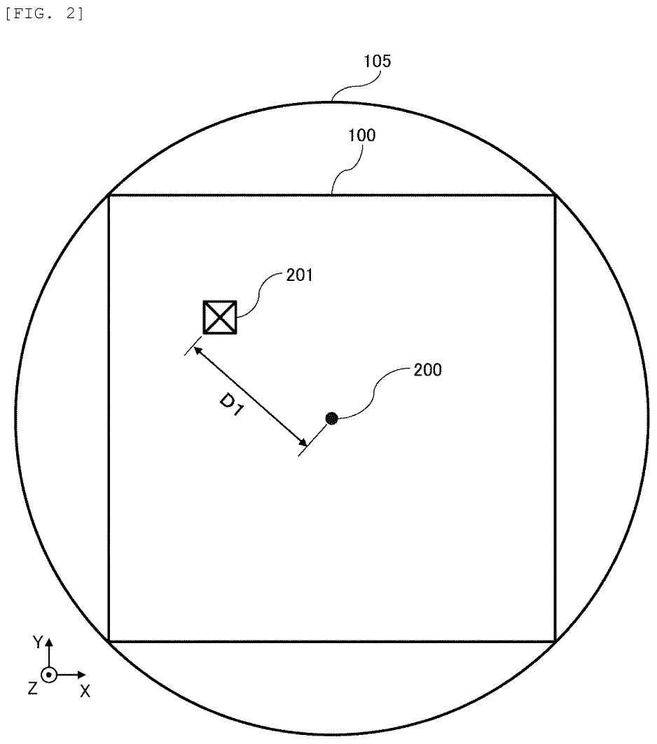

The alignment marker will be described with reference to FIG. 2. FIG. 2 illustrates an alignment marker 201 created on the surface of the sample 100 at a position from a holder center 200 that is the center of the sample holder 105 by a distance D1. The alignment marker 201 is created, for example, as an indentation by a Vickers cone under the optical microscope or as an ion beam mark by a focused ion beam (FIB) SEM. To improve the throughput of detailed observation of foreign substances and defects on the sample surface, it is desirable to detect the alignment marker 201 serving as the reference point for specifying the position on the sample 100 in a short time without changing an observation magnification. Therefore, in Embodiment 1, a guide marker having a shape indicating a direction in which the alignment marker 201 is present is created on the sample 100, the sample holder 105, or the sample stage 106.

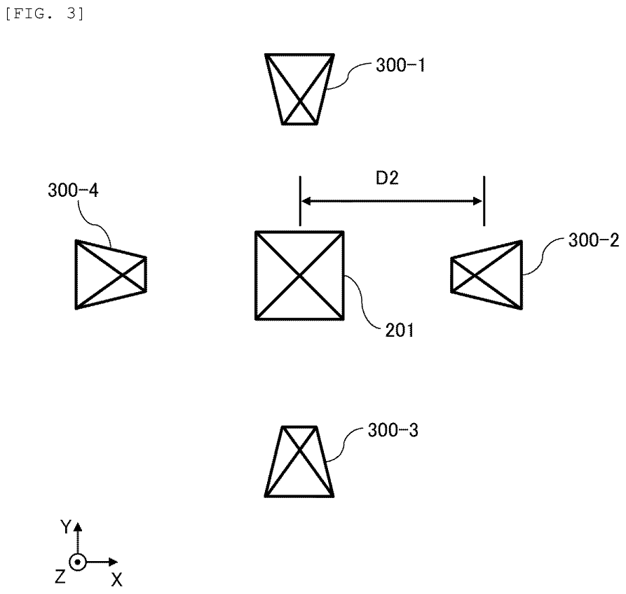

A guide marker will be described with reference to FIG. 3. FIG. 3 illustrates four guide markers 300 each having a trapezoidal shape and created at a position from the alignment marker 201 by a distance D2. The guide marker 300 in FIG. 3 indicates a direction from a lower base to an upper base of the trapezoid, and the alignment marker 201 is present in the direction indicated by the guide marker 300. The shape of the guide marker 300 is not limited to a trapezoid, and may be a shape indicating one direction, for example, an isosceles triangle or an arrow shape. Similarly to the alignment marker 201, the guide marker 300 is created, for example, as an indentation by a Vickers cone under the optical microscope or as an ion beam mark by a FIB-SEM.

By arranging the guide markers 300 as illustrated in FIG. 3 around the alignment marker 201, it is possible to detect the alignment marker 201 deviated from the field of view of the charged particle beam apparatus in a relatively short time. That is, by detecting the guide marker 300, the alignment marker 201 can be detected by moving the field of view in the direction indicated by the guide marker 300. To detect the guide marker 300 without changing the observation magnification, it is preferable that at least one guide marker 300 is arranged in the field of view at the observation magnification when the alignment marker 201 is observed by the charged particle beam apparatus.

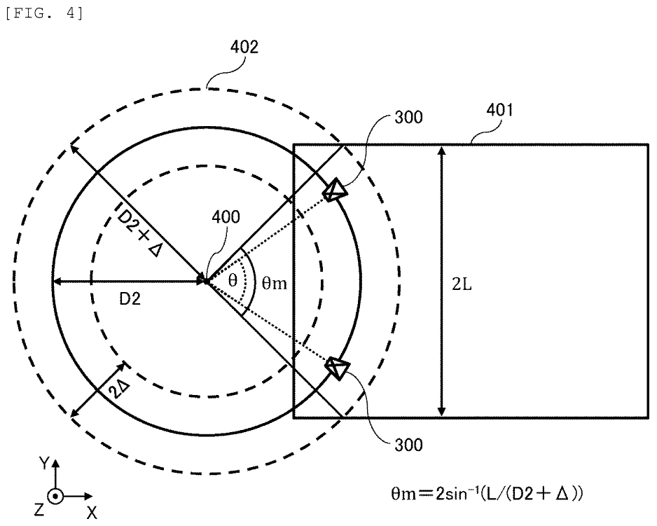

A preferred arrangement of the guide markers 300 will be described with reference to FIG. 4. When two of the guide markers 300 arranged at positions from a center 400 of the alignment marker by a distance D2 are located within both ends of short sides of a field of view 401 at the observation magnification when observing the alignment marker 201, a central angle θ of the two guide markers 300 is set to satisfy θm≥0. Here, θm is expressed by the following equation.

θm=2 sin⁻¹(L/ (D2+Δ)) (equation 1)

Here, 2L is a length of the short side of the field of view 401, and Δ is an error of the distance D2. The error Δ includes at least one of an error related to the arrangement of the alignment marker 201 or the guide marker 300, an error related to distance measurement, and an error related to the movement of the sample stage 106. A maximum error line 402 indicated by a dotted circle has a radius of D2+Δ.

That is, when the central angle θ of the two guide markers 300 is equal to or less than the value of (Equation 1), since at least one guide marker 300 is included in the field of view 401, the guide marker 300 can be detected without changing the observation magnification, and the field of view 401 can be moved in the direction indicated by the guide marker 300. Since the field of view 401 when the sample 100 gripped by the sample holder 105 is put into the charged particle beam apparatus is in the vicinity of the holder center 200, it is preferable that an initial guide marker indicating the guide marker 300 or the alignment marker 201 is arranged in the vicinity of the holder center 200.

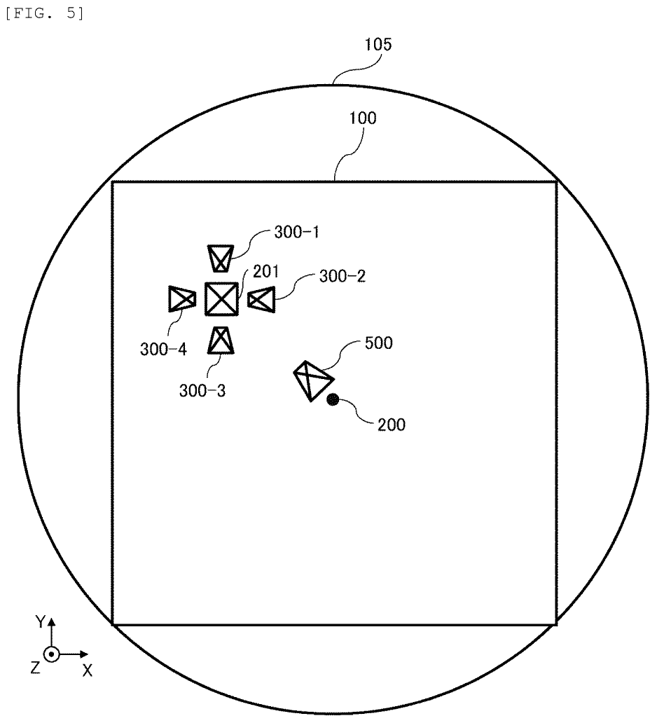

The initial guide marker will be described with reference to FIG. 5. FIG. 5 illustrates an initial guide marker 500 having a trapezoidal shape and created in the vicinity of the holder center 200 which is the center of the sample holder 105. Similarly to the guide marker 300, the initial guide marker 500 in FIG. 5 indicates a direction from a lower base to an upper base of the trapezoid, and the guide marker 300 or the alignment marker 201 is present in the direction indicated by the initial guide marker 500. The shape of the initial guide marker 500 is not limited to a trapezoid, and may be an isosceles triangle or an arrow shape. The initial guide marker 500 is also created as an indentation by a Vickers cone or an ion beam mark by FIB-SEM.

The initial guide marker 500 is preferably disposed in the field of view 401 when the sample 100 is placed in the charged particle beam apparatus. That is, the initial guide marker 500 is preferably disposed within a distance L from the holder center 200 that is half the short side of the field of view 401 at the observation magnification when observing the alignment marker 201. The initial guide marker 500 disposed within the distance L from the holder center 200 is detected by the field of view 401 when the sample 100 is placed in the charged particle beam apparatus.

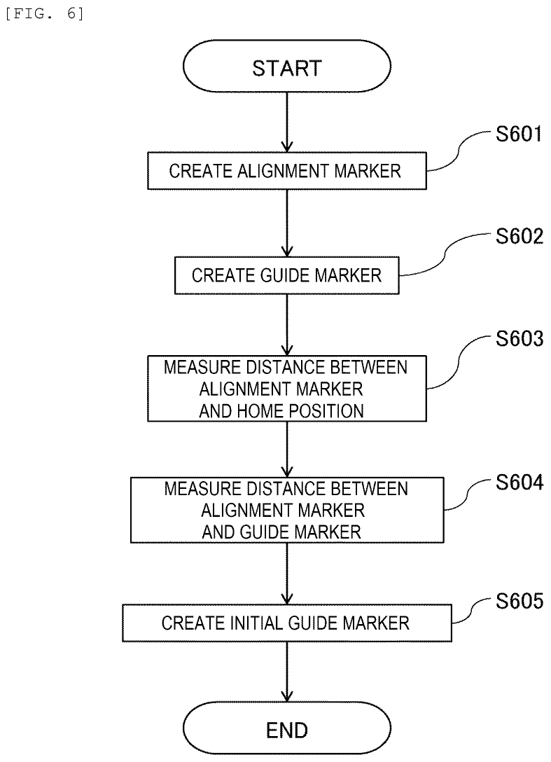

An example of a processing flow of creating each marker will be described for each step with reference to FIG. 6.

### S601

The alignment marker 201 is created under a first observation apparatus different from the charged particle beam apparatus used for the detailed observation. The alignment marker 201 is created on at least one of the sample 100, the sample holder 105, and the sample stage 106 as the reference point for specifying a position on the sample 100. The first observation apparatus is, for example, an optical microscope. The first observation apparatus is not limited to an optical microscope, and may be any surface shape measurement apparatus that performs shape measurement using a reflected signal of a probe, such as a scanning white interference microscope (CSI) or an electron microscope EDS.

### S602

The guide marker 300 is created around the alignment marker 201 under the first observation apparatus. The guide marker 300 is created such that the alignment marker 201 is present in the direction indicated by the guide marker 300. The central angle θ formed by two adjacent guide markers 300 in the alignment marker 201 is preferably within a value calculated by (Equation 1).

### S603

The distance D1 between the alignment marker 201 and the holder center 200, which is a HOME position, is measured using the first observation apparatus. The value of the measured distance D1 is stored in a storage device of the control unit 111.

### S604

The distance D2 between the alignment marker 201 and the guide marker 300 is measured using the first observation apparatus. The value of the measured distance D2 is stored in the storage device of the control unit 111.

### S605

The initial guide marker 500 is created in the vicinity of the holder center 200 under the first observation apparatus. The initial guide marker 500 is created such that the alignment marker 201 or the guide marker 300 is present in the direction indicated by the initial guide marker 500. A distance between the initial guide marker 500 and the holder center 200 is preferably within the distance L that is half the short side of the field of view 401 at the observation magnification when observing the alignment marker 201.

According to the processing flow described with reference to FIG. 6, the alignment marker 201, the guide marker 300, and the initial guide marker 500 are created on the sample 100, the sample holder 105, or the sample stage 106. The guide marker 300 and the initial guide marker 500 are used to detect the alignment marker 201.

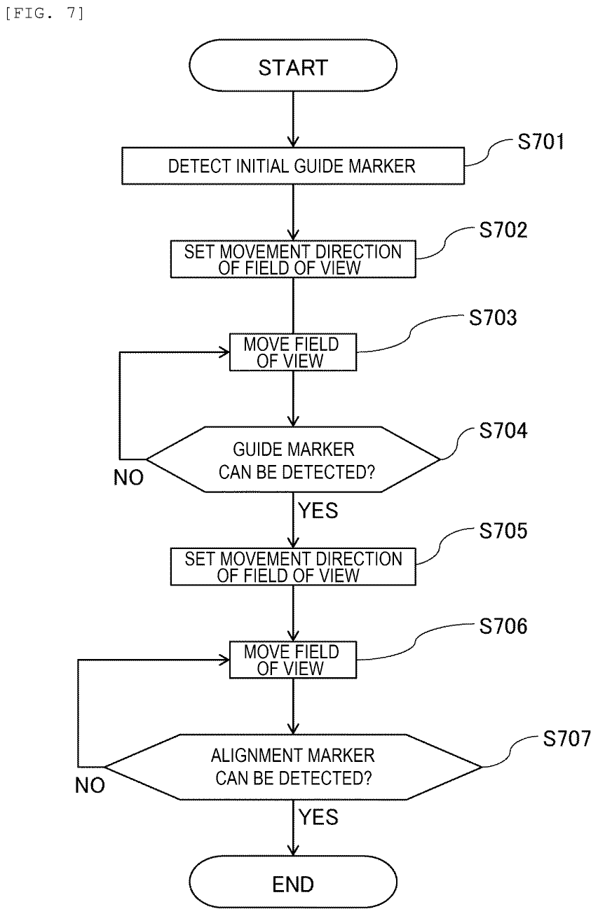

An example of a processing flow of detecting the alignment marker 201 will be described for each step with reference to FIG. 7.

### S701

The control unit 111 detects the initial guide marker 500 based on the observation image. A template matching method or a feature point detection method is used to detect the initial guide marker 500.

### S702

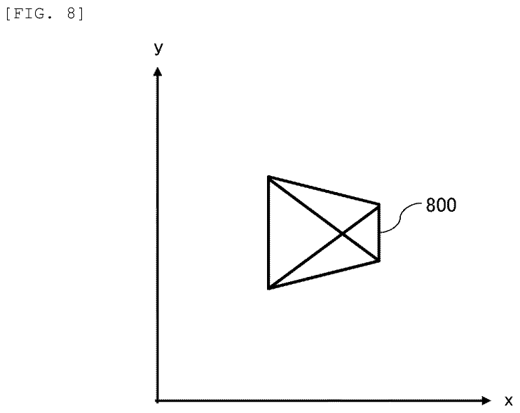

The control unit 111 sets a movement direction of the field of view 401 based on a shape of the initial guide marker 500 detected in S701. For example, the movement direction is set by rotating a template image 800 having the same shape as the initial guide marker 500 and indicating an x-axis positive direction as illustrated in FIG. 8 to match the detected initial guide marker 500. More specifically, a correlation value of a pixel value with the initial guide marker 500 is calculated every time the template image 800 is rotated by a predetermined angle, for example, 0.5 degrees, and the movement direction is set based on a rotation angle at which the correlation value is maximized.

### S703

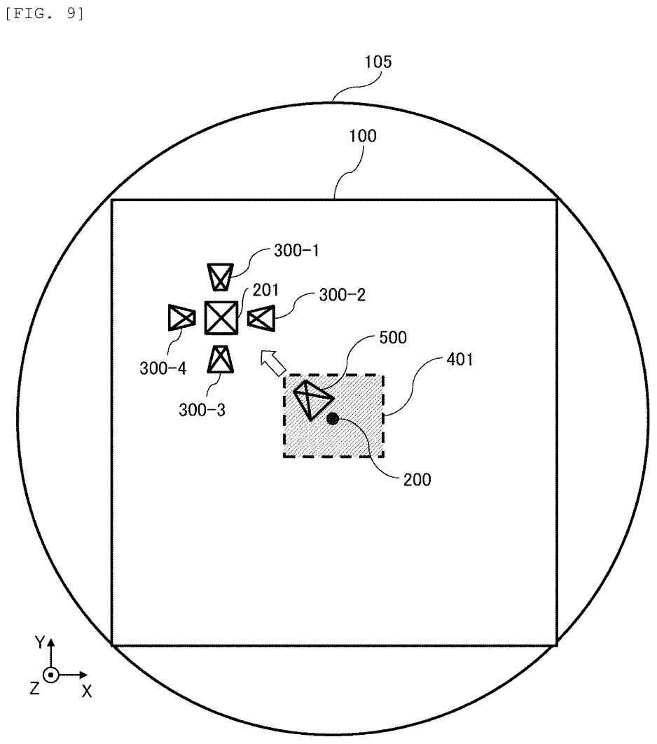

The control unit 111 moves the field of view 401 in the movement direction set in S702. The movement of the field of view 401 is implemented by the movement of the sample stage 106 or a change of the electron beam irradiation field by the deflector 103. FIG. 9 illustrates an example of the field of view 401 moved based on the shape of the initial guide marker 500. In FIG. 9, the field of view 401 is moved in a direction of a white arrow that is a direction indicated by the initial guide marker 500 detected in the field of view 401. A movement distance of the field of view 401 is set to a predetermined value, for example, the distance L that is half the short side of the field of view 401.

### S704

The control unit 111 determines whether the guide marker 300 can be detected in the field of view 401 after the movement. Similarly to the initial guide marker 500, a template matching method or a feature point detection method is used to detect the guide marker 300. If the guide marker 300 is detected, the processing proceeds to S705, and if the guide marker 300 is not detected, the processing returns to S703. That is, the movement of the field of view 401 in S703 is repeated until the guide marker 300 is detected in S704. If a movement limit of the field of view 401 is reached without detecting the guide marker 300, the field of view 401 may be returned to the holder center 200, which is the HOME position, and the processing may be resumed from S701 or an error message may be displayed.

The movement of the field of view 401 in S703 may be implemented based on the distance D1 between the alignment marker 201 and the holder center 200 which is measured in S603 of FIG. 6 and stored in the storage device of the control unit 111. When the field of view 401 is moved based on the distance D1, if the guide marker 300 cannot be detected in S704, the error message is displayed and the processing flow is ended.

### S705

The control unit 111 sets the movement direction of the field of view 401 based on the shape of the guide marker 300 detected in S704.

### S706

The control unit 111 moves the field of view 401 in the movement direction set in S705. The movement distance of the field of view 401 is set to a predetermined value, for example, the distance L that is half the short side of the field of view 401.

### S707

The control unit 111 determines whether the alignment marker 201 can be detected in the field of view 401 after the movement. Similarly to the initial guide marker 500, a template matching method or a feature point detection method is used to detect the alignment marker 201. A method having higher detection accuracy such as point detection using a differential image may be used. If the alignment marker 201 can be detected, the processing flow ends, and if the alignment marker 201 cannot be detected, the processing returns to S706. That is, the movement of the field of view 401 in S706 is repeated until the alignment marker 201 is detected in S707. When the movement limit of the field of view 401 is reached without detecting the alignment marker 201, the error message is displayed and the processing flow is ended.

The movement of the field of view 401 in S706 may be implemented based on the distance D2 between the alignment marker 201 and the guide marker 300 which is measured in S604 of FIG. 6 and stored in the storage device of the control unit 111. When the field of view 401 is moved based on the distance D2, if the alignment marker 201 cannot be detected in S707, the error message is displayed and the processing flow is ended. The distance D2 may be indicated by the shape of the guide marker 300.

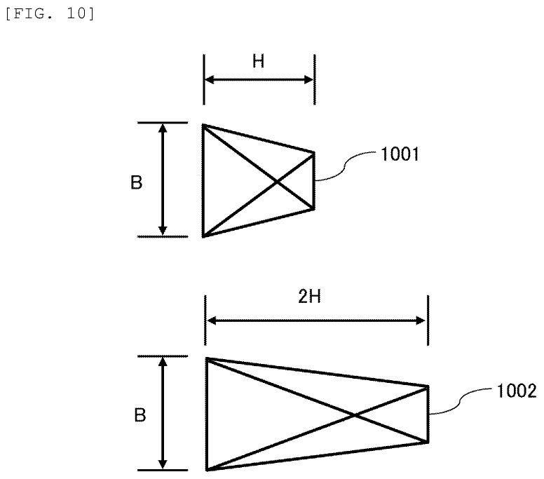

Examples of a guide marker indicating the distance will be described with reference to FIG. 10. FIG. 10 illustrates a short-distance guide marker 1001 indicating a short distance and a long-distance guide marker 1002 indicating a long distance. Although both of the two guide markers have a trapezoidal shape having a lower base of the same length B, a height of the long-distance guide marker 1002 is 2H which is twice a height H of the short-distance guide marker 1001. That is, in the two guide markers illustrated in FIG. 10, the distance is indicated by a ratio between the lower base and the height. When the guide marker indicating the distance is created, it is necessary to set the distance between the guide marker and the alignment marker 201 before creating the guide marker.

According to the processing flow described with reference to FIG. 7, the alignment marker 201 can be detected without changing the observation magnification. That is, since the alignment marker 201 can be detected in a shorter time, the throughput of detailed observation of foreign substances or defects on the sample surface detected under the first observation apparatus can be improved.

### Embodiment 2

Embodiment 1 describes that the alignment marker 201 is detected by moving the field of view 401 in the direction indicated by the guide markers 300 arranged around the alignment marker 201. Embodiment 2 describes that a link marker that is a guide marker for sequentially detecting a plurality of the alignment markers 201 will be described. Since a part of configurations and functions described in Embodiment 1 can be applied in Embodiment 2, the same configurations and functions are denoted by the same reference numerals, and description thereof will be omitted.

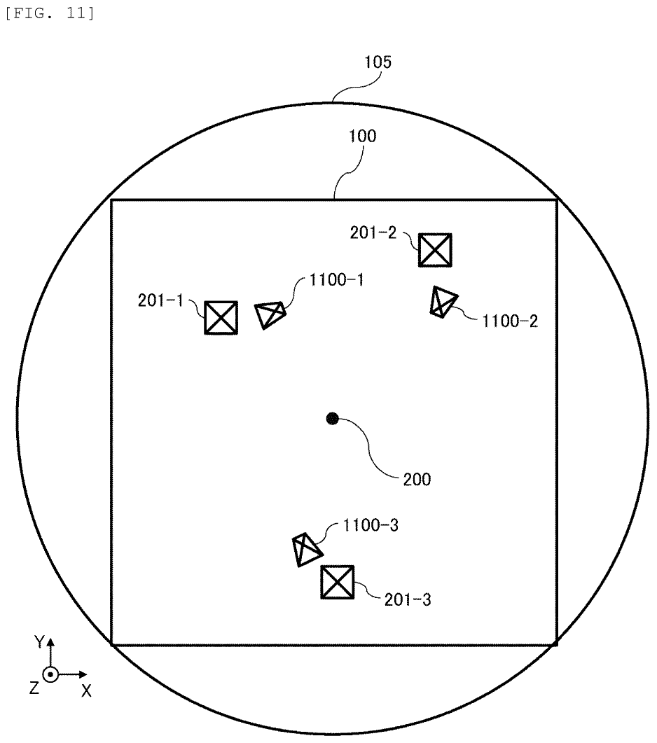

The link marker will be described with reference to FIG. 11. FIG. 11 illustrates link markers 1100 each having a trapezoidal shape and created in the vicinity of each of three alignment markers 201. Similar to the guide marker 300, the link marker 1100 in FIG. 11 indicates a direction from a lower base to an upper base of the trapezoid, and the alignment marker 201 is present in the direction indicated by the link marker 1100. The shape of the link marker 1100 is not limited to a trapezoid, and may be an isosceles triangle or an arrow shape. Similarly to the guide marker 300, the link marker 1100 is also created as an indentation by a Vickers cone or an ion beam mark by FIB-SEM.

A link marker 1100-1 created in the vicinity of the alignment marker 201-1 indicates an alignment marker 201-2. A link marker 1100-2 in the vicinity of the alignment marker 201-2 indicates an alignment marker 201-3, and a link marker 1100-3 in the vicinity of the alignment marker 201-3 indicates the alignment marker 201-1. In this way, by sequentially detecting the alignment markers 201 indicated by the link markers 1100 starting from one alignment marker 201 and the link marker 1100 in the vicinity thereof, the link markers 1100 are created such that all the alignment markers 201 can be detected.

The link marker 1100 is preferably arranged in the field of view when observing the alignment marker 201. That is, the link marker 1100 is preferably arranged within the distance L from the alignment marker 201, which is half of the short side of the field of view 401. The link marker 1100 arranged within the distance L from the alignment marker 201 is detected by the field of view 401 when observing the alignment marker 201.

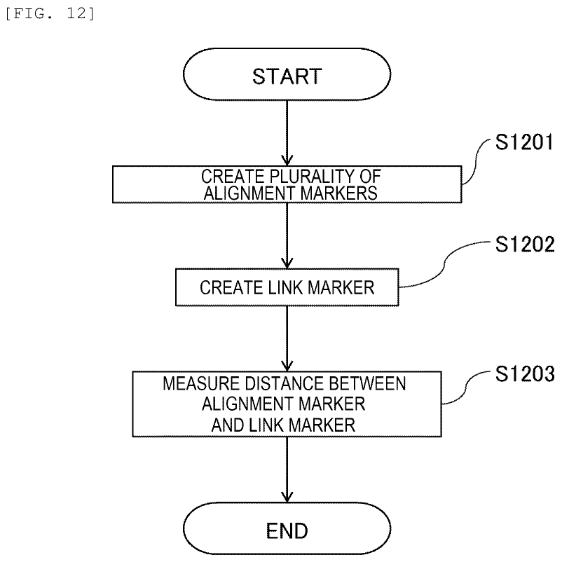

An example of a processing flow of creating the link marker 1100 will be described for each step with reference to FIG. 12.

### S1201

The plurality of alignment marker 201 are created under a first observation apparatus different from the charged particle beam apparatus used for the detailed observation. The plurality of alignment markers 201 are created on at least one of the sample 100, the sample holder 105, and the sample stage 106. The first observation apparatus is, for example, an optical microscope, a scanning white interference microscope (CSI), or an electron microscope EDS.

### S1202

The link marker 1100 is created in the vicinity of the alignment marker 201 under the first observation apparatus. The link marker 1100-1 in the vicinity of the alignment marker 201-1 is created to indicate the alignment marker 201-2. The link marker 1100-2 in the vicinity of the alignment marker 201-22/32 2 is created to indicate the alignment marker 201-3, and the link marker 1100-3 is created to indicate the alignment marker 201-1. The numbers of alignment markers 201 and link markers 1100 are not limited to three. When the numbers of alignment markers 201 and link markers 1100 are N, a link marker 1100-N indicates the alignment marker 201-1.

### S1203

A distance between the alignment marker 201 indicated by the link marker 1100 and the link marker 1100 is measured using the first observation apparatus. The value of the measured distance is stored in a storage device of the control unit 111. For the measurement of the distance, a scanning white interference microscope (CSI) or an electron microscope EDS, which is a surface shape measurement apparatus for measuring a depth of the sample surface. By using the surface shape measurement apparatus, edges of the alignment marker 201 and the link marker 1100 can be detected more accurately, and therefore the accuracy of the measured distance value is improved.

According to the processing flow described with reference to FIG. 12, the plurality of alignment markers 201 and the link markers 1100 arranged in the vicinity of thereof are created on the sample 100, the sample holder 105, or the sample stage 106. The link marker 1100 is used to sequentially detect the plurality of alignment markers 201.

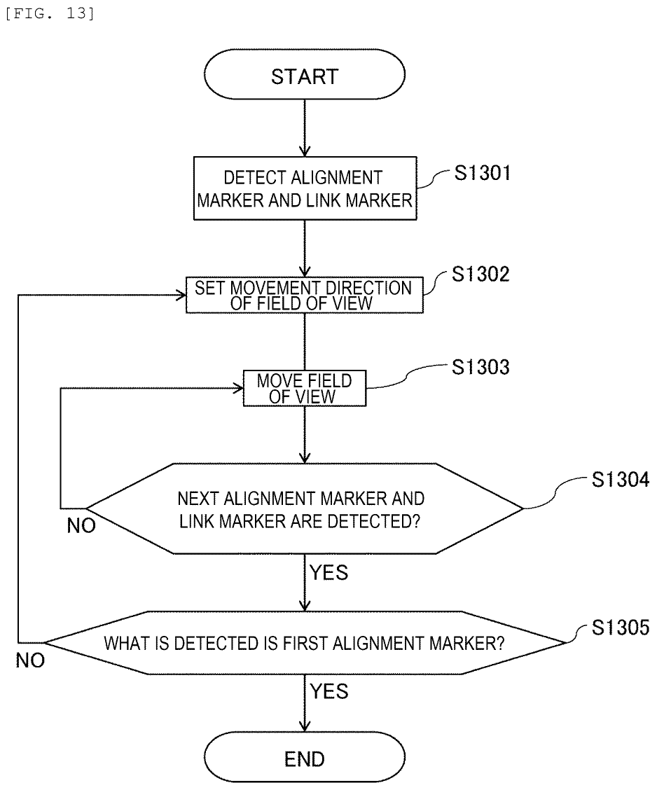

An example of a processing flow of sequentially detecting the plurality of alignment markers 201 will be described for each step with reference to FIG. 13.

### S1301

The control unit 111 detects the alignment marker 201 and the link marker 1100 arranged in the vicinity thereof from an observation image. The movement of the field of view 401 from the holder center 200, which is the HOME position, may be the same as in S701 of FIG. 7, or may be performed manually. A template matching method or a feature point detection method is used to detect the alignment markers 201 and the link marker 1100. Since the link markers 1100 are arranged such that all the alignment markers 201 can be detected by following the directions indicated by the link markers 1100, the marker detected in S1301 may be a maker other than the link marker 1100-1.

### S1302

The control unit 111 sets a movement direction of the field of view 401 based on the shape of the link marker 1100 detected in S1301.

### S1303

The control unit 111 moves the field of view 401 in the movement direction set in S1302. The movement distance of the field of view 401 is set to a predetermined value, for example, the distance L that is half the short side of the field of view 401.

### S1304

The control unit 111 determines whether the next alignment marker 201 and link marker 1100 can be detected in the field of view 401 after the movement. If the next alignment marker 201 and link marker 1100 can be detected, the processing proceeds to S1305, and if the next alignment marker 201 and link marker 1100 cannot be detected, the processing returns to S1303. That is, the movement of the field of view 401 in S1303 is repeated until the next alignment marker 201 and link marker 1100 are detected in S1304. If the movement limit of the field of view 401 is reached without detecting the next alignment marker 201 and link marker 1100, an error message is displayed and the processing flow is ended.

The movement of the field of view 401 in S1303 may be implemented based on the distance between the alignment marker 201 and the link marker 1100 indicated by the link marker 1100, which is measured in S1203 of FIG. 12 and stored in the storage device of the control unit 111. Also when the field of view 401 is moved based on a distance read from the storage device, if the next alignment marker 201 and link marker 1100 cannot be detected in S1304, an error message is displayed and the processing flow is ended.

### S1305

The control unit 111 determines whether the alignment marker 201 detected in S1304 is the same as the alignment marker 201 detected in S1301. If the alignment markers 201 are the same, the processing flow ends, and if the alignment markers 201 are not the same, the processing returns to S1302, and the movement direction of the field of view 401 is set based on the shape of the link marker 1100 detected in S1304. That is, the sequential detection of the plurality of alignment markers 201 is repeated until the alignment marker 201 detected in S1304 is the same as the alignment marker 201 detected first.

According to the processing flow described with reference to FIG. 13, the plurality of alignment markers 201 are sequentially detected while following the directions indicated by the link markers 1100. By sequentially detecting the plurality of alignment markers 201, the throughput of detailed observation of foreign substances or defects on the sample surface detected under the first observation apparatus can be improved.

A plurality of embodiments of the invention have been described above. The invention is not limited to the above embodiments, and can be embodied by modifying components without departing from the gist of the invention. A plurality of components disclosed in the above embodiments may be combined appropriately. A part of components may be deleted from all components disclosed in the above embodiments.

### REFERENCE SIGNS LIST

100: sample
101: electron source
102: condenser lens
103: deflector
104: objective lens
105: sample holder
106: sample stage
107: detector
111: control unit
112: input unit
113: display unit
200: holder center
201: alignment marker
300: guide marker
400: center of alignment marker
401: field of view
402: maximum error line
500: initial guide marker
800: template image
1001: short-distance guide marker
1002: long-distance guide marker
1100: link marker

1.-9. (canceled)

10. A charged particle beam apparatus comprising:
a sample holding portion configured to hold a sample;
a charged particle beam source configured to irradiate the sample with a charged particle beam;
a detector configured to detect a secondary particle emitted from the sample and output a detection signal; and
a control unit configured to generate an observation image of the sample based on the detection signal and control each unit, wherein
the sample is provided with an alignment marker serving as a reference point for specifying a position on the sample and a guide marker having a shape indicating a direction in which the alignment marker is present,
an initial guide marker having a shape indicating a direction in which the alignment marker is present is further provided in a vicinity of a center of the sample holding portion, and
the control unit detects the initial guide marker based on the observation image, moves a field of view in the direction indicated by the initial guide marker to detect the guide marker, and moves the field of view in the direction indicated by the guide marker.

11. The charged particle beam apparatus according to claim 10, wherein
at least one of the guide markers is disposed in a field of view at an observation magnification when the alignment marker is observed.

12. The charged particle beam apparatus according to claim 11, wherein
a central angle θ formed by two of the adjacent guide markers in the alignment marker satisfies θ≤2 sin⁻¹(L/(D2+Δ)) when a short side of the field of view is 2L, a distance between the guide marker and the alignment marker is D2, and an error of the D2 is Δ.

13. A charged particle beam apparatus comprising:
a sample holding portion configured to hold a sample;
a charged particle beam source configured to irradiate the sample with a charged particle beam;
a detector configured to detect a secondary particle emitted from the sample and output a detection signal; and
a control unit configured to generate an observation image of the sample based on the detection signal and control each unit, wherein
the sample is provided with a plurality of alignment markers each serving as a reference point for specifying a position on the sample, and is further provided with a link marker having a shape indicating a direction in which a second alignment marker is present in a vicinity of a first alignment marker, and
the control unit detects the link marker based on the observation image and moves the field of view in the direction indicated by the link marker.

14. The charged particle beam apparatus according to claim 13, wherein
the control unit moves the field of view based on a distance between the first alignment marker and the second alignment marker measured in advance by an observation apparatus different from the charged particle beam apparatus.

15. The charged particle beam apparatus according to claim 14, wherein
the observation apparatus is a surface shape measurement apparatus that measures a depth of a sample surface together with an observation image of the sample surface.

16. The charged particle beam apparatus according to claim 10, wherein
the guide marker further has a shape indicating a distance to the alignment marker, and
the control unit moves the field of view based on the distance indicated by the guide marker.

17. An alignment marker detection method for detecting an alignment marker serving as a reference point for specifying a position on a sample held by a sample holding portion, based on an observation image generated by irradiating the sample with a charged particle beam, the alignment marker detection method comprising:
a first detection step of detecting, based on the observation image, an initial guide marker provided in a vicinity of a center of the sample holding portion and having a shape indicating a direction in which the alignment marker is present;
a first movement step of moving a field of view in the direction indicated by the initial guide marker;
a second detection step of detecting, based on the observation image, a guide marker having a shape indicating a direction in which the alignment marker is present; and
a second movement step of moving the field of view in the direction indicated by the guide marker.
